(19) United States
(12) Patent Application Publication
(10) Pub. No.: US 2011/0094573 A1
(43) Pub. Date: Apr. 28, 2011

(54) Solar cell and method for fabricating the same

(75) Inventors: Chien-Liang Wu, Pingtung County (TW); Jun-Chin Liu, Hsinchu City (TW); Ming-Jyh Chang, Keelung City (TW); Hsing-Hua Wu, Kaohsiung City (TW); Yu-Ming Wang, Taichung City (TW)

(73) Assignee: Industrial Technology Research Institute, Hsinchu (TW)

(21) Appl. No.: 12/653,625

(22) Filed: Dec. 15, 2009

(30) Foreign Application Priority Data
Oct. 23, 2009 (TW) 98135966

(51) Int. Cl. H01L 31/0216; H01L 31/00; H01L 31/0224; H01L 31/0232

(52) U.S. Cl. 136/255; 136/256; 438/72; 257/E31.12; 257/E31.126; 257/E31.127

(57) ABSTRACT

A solar cell and a method for fabricating the same are provided. The solar cell includes a first electrode, a second electrode, a photoelectric conversion layer and a non-conductive reflector. The first electrode including a nano-metal transparent conductive layer is disposed on a transparent substrate. The nano-metal transparent conductive layer substantially contacts with the photoelectric conversion layer. The second electrode is disposed between the photoelectric conversion layer and the transparent substrate. The photoelectric conversion layer is disposed between the first and the second electrodes. The non-conductive reflector is disposed on the first electrode.

### CROSS-REFERENCE TO RELATED APPLICATION

This application claims the priority benefit of Taiwan application serial no. 98135966, filed on Oct. 23, 2009. The entirety of the above-mentioned patent application is hereby incorporated by reference herein and made a part of this specification.

### BACKGROUND OF THE INVENTION

1. Field of the Invention

The present invention relates to a solar cell. More particularly, the present invention relates to a solar cell using nano-metal as a transparent conductive film.

2. Description of Related Art

Solar energy is a clean, pollution-free and inexhaustible energy. Therefore, when problems of pollution and shortage of petroleum energy are encountered, how to effectively use the solar energy becomes a focus of attention. Since a solar cell can directly convert the solar energy into electric power, it becomes a development priority of using the solar energy.

A silicon-based solar cell is a commonly used solar cell in the art, and a principle of the silicon-based solar cell is to add impurities to a semiconductor material (silicon) with a high-purity, so as to achieve different properties. When sunlight irradiates the semiconductor material of the solar cell, energy carried by photons can probably stimulate electrons in the semiconductor material to generate electron-hole pairs. The electrons and the holes are all influenced by a built-in potential, wherein the holes move towards an electric field, and the electrons move towards an opposite direction. If the solar cell and a load are connected through a lead to form a loop, currents can flow through the load, and this is a power generation principle of the solar cell.

The silicon-based solar cells are roughly divided into crystalline silicon solar cells and silicon thin film solar cells. Since the silicon thin film solar cell has advantages of low cost, easy to be mass-produced and simple modularisation process, etc., research and development of the silicon thin film solar cell are still development trends of the solar cell. Generally, the solar cells can be roughly divided into superstrate solar cells and substrate solar cells according to incident directions of the sunlight. In a superstrate silicon thin film solar cell, after the sunlight enters the substrate, it is absorbed by an active layer, and after the remained sunlight penetrate through a back electrode, it is reflected by a back reflector, and is again used by the active layer. Since an amount of the reflected light influences a performance of the solar cell, if more reflected light are required to be again used by the active layer, a transmittance characteristic of the back electrode can significantly influence a light absorption efficiency of the solar cell.

In a solar cell manufactured by Oerlikon Company, transparent conductive oxide (TCO) serves as the back electrode, and white paint serves as the back reflector.

To pull currents from the back electrode, a thickness of the TCO has to be increased to 0.5 μm-5 μm, so as to obtain a better conductivity. However, in case that such thick TCO is used, the light transmittance of the back electrode is significantly decreased, which may influence a reflectance of the reflector. Moreover, to produce a front electrode and the back electrode of the solar cell, two sets of low pressure chemical vapor deposition (LPCVD) vacuum systems are generally used to respectively produce two layers of TCO, so that a material cost thereof is relatively high, and a fabrication process thereof is complicated.

### SUMMARY OF THE INVENTION

Accordingly, the present invention is directed to a solar cell and a method for fabricating the same, in which a nano-metal transparent conductive layer is used as a material of a back electrode.

The present invention provides a solar cell. The solar cell includes a first electrode, a second electrode, a photoelectric conversion layer and a non-conductive reflector. The first electrode including a nano-metal transparent conductive layer is disposed on a transparent substrate. The nano-metal transparent conductive layer substantially contacts with the photoelectric conversion layer. The second electrode is disposed between the photoelectric conversion layer and the transparent substrate. The photoelectric conversion layer is disposed between the first and the second electrodes. The non-conductive reflector is disposed on the first electrode.

The present invention further provides a method for fabricating a solar cell. The method can be described as follows. First, a second electrode is formed on a transparent substrate, and then a photoelectric conversion layer is formed on the second electrode. Next, a first electrode is formed on the photoelectric conversion layer, wherein the first electrode includes a nano-metal transparent conductive layer, and the nano-metal transparent conductive layer substantially contacts with the photoelectric conversion layer. Next, a non-conductive reflector is formed on the first electrode.

According to the above descriptions, the solar cell of the present invention uses the nano-metal transparent conductive layer as the material of the back electrode, the nano-metal transparent conductive layer has characteristics of high light transmittance and low resistance, which avails increasing a reflectance of the reflector and improving a performance of the solar cell.

Moreover, in the method of fabricating the solar cell, the transparent electrode is fabricated through a non-vacuum coating system, so as to apply the nano-metal transparent conductive layer to the silicon thin film solar cell. Therefore, the equipment cost and the material cost are greatly reduced, and the method can be integrated to an existing fabrication process of the solar cells, so that the fabrication process can be simple and quick, which avails a mass production of the solar cell.

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a solar cell according to an embodiment of the present invention.

FIG. 2A is a diagram illustrating a transparent conductive film fabricated according to an experiment 1.

FIG. 2B is an image of a transparent conductive film fabricated according to the experiment 1 that is observed under an optical microscope.

FIG. 2C is a curve diagram illustrating a relationship between transmission rate of a transparent conductive film fabricated according to the experiment 1 and light wavelength.

FIG. 2D is an I-V curve diagram of a transparent conductive film fabricated according to the experiment 1.

FIG. 2E is a curve diagram illustrating relationships respectively between reflectances of a transparent conductive film fabricated according to the experiment 1 and a conventional TCO and light wavelength.

FIG. 3A is a diagram illustrating a transparent conductive film fabricated according to an experiment 2.

FIG. 3B is an image of a transparent conductive film fabricated according to the experiment 2 that is observed under an optical microscope.

FIG. 3C is a curve diagram illustrating a relationship between transmission rate of a transparent conductive film fabricated according to the experiment 2 and light wavelength.

FIG. 3D is an I-V curve diagram of a transparent conductive film fabricated according to the experiment 2.

### DESCRIPTION OF THE EMBODIMENTS

In a nano-metal organic solution, nano-metal ions are stably suspended in the liquid. Therefore, when being stimulated by a chemical reductant or light irradiation, etc., the nano-metal ions can obtain electrons to gain a metal state. In the present invention, the nano-metal ion solution is used to produce a nano-metal transparent conductive layer having a high light transmittance and a low resistance to serve as a back electrode of a solar cell, so as to increase the light transmittance and a whole reflectance, and improve a performance of the solar cell.

The present invention will now be described more fully with reference to the accompanying drawings. However, the present invention can be implemented by different approaches, and are not limited by the embodiment of the present invention. Moreover, for clarity's sake, in the figures, sizes of different layers and relative sizes are not necessarily drawn to scale.

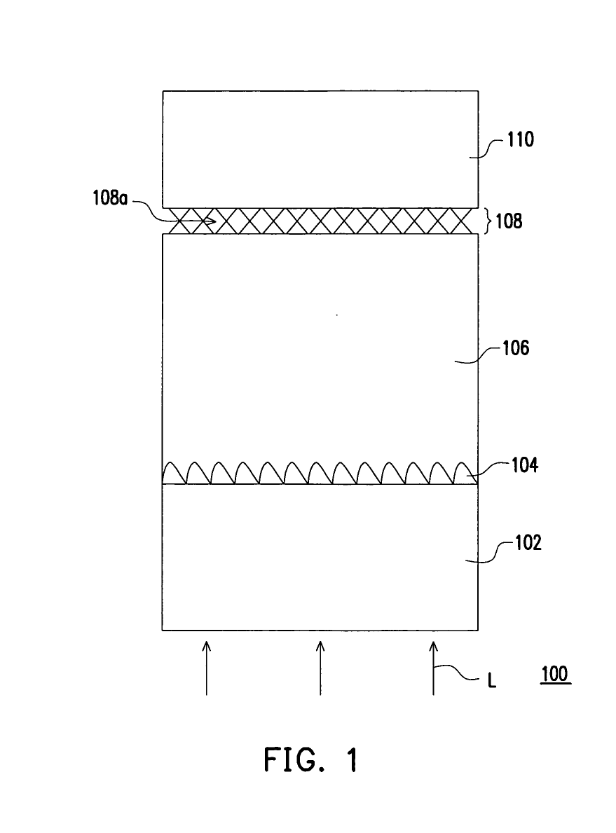

FIG. 1 is a cross-sectional view of a solar cell according to an embodiment of the present invention.

Referring to FIG. 1, the solar cell 100 includes a transparent substrate 102, and an electrode 104, a photoelectric conversion layer 106, an electrode 108 and a non-conductive reflector 110 disposed on the transparent substrate 102. The electrode 108 is disposed above the transparent substrate 102, and the electrode 104 is disposed between the transparent substrate 102 and the electrode 108. The photoelectric conversion layer 106 is disposed between the electrodes 104 and 108. The non-conductive reflector 110 is disposed on the electrode 108.

A material of the transparent substrate 102 is, for example, glass, transparent resin or other suitable transparent materials. The transparent resin is, for example, polyethylene terephthalate (PET), polyethylene naphthalate (PEN), polycarbonate (PC), polyethersulfone (PES) or polyimide (PI).

Generally, structures of the solar cells can be divided into superstrate structures and substrate structures according to incident directions of the sunlight. The so-called superstrate structure refers to that a transparent electrode is first plated underneath the substrate, and then a photoelectric conversion layer and an opaque electrode are sequentially plated. Comparatively, the substrate structure refers to that the opaque electrode is first plated on the substrate, and then the photoelectric conversion layer and the transparent electrode are sequentially plated. The solar cell 100 of the present embodiment is, for example, a solar cell having the superstrate structure. Since the superstrate structure refers to that the sunlight is incident from a side of the substrate, light L is incident to internal of the solar cell 100 from the side of the transparent substrate 102, as that shown in FIG. 1.

The electrode 104 is disposed on the transparent substrate 102 to serve as a front electrode. A material of the electrode 104 can be transparent conductive oxide (TCO), which is, for example, indium tin oxide (ITO), indium zinc oxide (IZO), Al doped zinc oxide (AZO), Ga doped zinc oxide (GZO), In₂O₃, ZnO, TiO₂, SnO₂ or other transparent conductive materials. In an embodiment, to improve the efficiency of the solar cell 100, a surface of the electrode 104 can be an uneven surface having texture structures, so as to reduce a light reflecting amount. The uneven surface having the texture structures can increase a scattering chance of the light in the solar cell 100 and reduce a reflection of the incident light, so as to increase a travel distance of the incident light in the photoelectric conversion layer. Therefore, a surface of the electrode 104 serving as the front electrode is generally fabricated into a V-shape groove, a pyramid shape or a reversed pyramid shape.

A method of forming the electrode 104 is to form the TCO on the transparent substrate 102 according to, for example, a chemical vapor deposition (CVD) process, a physical vapor deposition (PVD) process or a spray coating method. To improve the efficiency of the solar cell 100, a surface treatment can be performed to the TCO to form the uneven surface having the texture structures, so as to scatter the light and reduce the light reflecting amount. In an embodiment, a laser process can be selectively performed to cut the TCO into a shape required by the electrode 104.

The photoelectric conversion layer 106 is disposed on the electrode 104 to serve as an active layer. The photoelectric conversion layer 106 may have a single-layer structure or a tandem structure. A material of the photoelectric conversion layer 106 is, for example, amorphous silicon, microcrystalline silicon, polysilicon, CdS, CuInGaSe₂ (CIGS), CuInSe₂ (CIS), CdTe, organic materials or a multi-layer structure stacked by the above materials. In an embodiment, the photoelectric conversion layer 106 can be a PIN semiconductor stack structure having a P-type semiconductor layer, an N-type semiconductor layer and an intrinsic layer or a PN semiconductor stack structure without the intrinsic layer. In the present invention, a number of the material layers used in the photoelectric conversion layer 106 and structures thereof are not limited, which can be modified by those with ordinary skill in the art according to an actual demand.

The photoelectric conversion layer 106 is, for example, formed on the surface of the electrode 104 according to the CVD process after the electrode 104 is formed. In the P-type semiconductor layer or the N-type semiconductor layer of the photoelectric conversion layer 106, the P-type dopant or the N-type dopant can be doped in situ during the CVD process, or can be doped by using an ion implantation process after the CVD process is completed. In an embodiment, the photoelectric conversion layer 106 can be formed according to a plasma enhanced chemical vapor deposition (PECVD) process. In an embodiment, a laser cutting process can be selectively performed to produce a desired shape of the photoelectric conversion layer 106.

The electrode 108 is disposed on the photoelectric conversion layer 106 to serve as a back electrode. The electrode 108 includes a nano-metal transparent conductive layer, and the nano-metal transparent conductive layer substantially contacts with the photoelectric conversion layer 106. Namely, a single layer of the nano-metal transparent conductive layer can be used to serve as the electrode 108 (shown in FIG. 1). Alternatively, a combination of an electrode material layer and the nano-metal transparent conductive layer can be used to serve as the electrode 108 (not shown). In detail, the nano-metal transparent conductive layer may have a mesh structure, namely, the nano-metal transparent conductive layer has a plurality of voids 108a to facilitate the light penetrating through. In an embodiment, the nano-metal transparent conductive layer is formed by a plurality of interlaced metal nanowires, so that the voids 108a can be formed. The metal nanowire is a solid wire, and a diameter thereof is between 10 nm and 100 nm. Certainly, the structure of the nano-metal transparent conductive layer is not limited to the interlaced metal nanowires, which can also be interlaced nanotubes, nanoparticles aggregation or other nano-structure combinations having a plurality of the voids as long as the nano-sized metal material has a high light transmittance. A thickness of the nano-metal transparent conductive layer is approximately between 0.1 μm and 1 μm, a sheet resistance thereof is approximately between 0.01 ohms per square (Ω/□) and 50Ω/□, and a transmittance thereof is approximately between 70% and 90%. A material of the nano-metal transparent conductive layer is, for example, silver, gold, copper, aluminium or nickel.

A method of forming the electrode 108 is as follows. After the photoelectric conversion layer 106 is formed, the nano-metal organic solution is evenly coated on the surface of the photoelectric conversion layer 106 through a non-vacuum coating system, and then the liquid is dried under a low temperature of 50° C., so that a nano-metal mesh film is formed on the surface of the photoelectric conversion layer 106. In an embodiment, a method of coating the nano-metal organic solution on the photoelectric conversion layer 106 can be spin coating, surface coating, ink jetting, screen printing or other techniques without using a vacuum equipment.

It should be noticed that in the electrode 108 of the present embodiment, the nano-metal transparent conductive layer formed through the non-vacuum coating system is used to replace the conventional TCO formed through the vacuum coating system, and the pattern required by the electrode 108 can be directly formed without an additional laser cutting process, which avails greatly reducing an equipment cost and a material cost. Moreover, the aforementioned method of forming the electrode 108 can be integrated to an existing fabrication process of the solar cell, so that the fabrication process can be simple and quick, which avails a mass production of the solar cell.

The non-conductive reflector 110 is disposed on the electrode 108 to serve as a back reflector. The non-conductive reflector 110 includes a white non-conductive material, which can be an organic polymer material, a non-conductive white paint, or other non-conductive materials having a high reflectance. The organic polymer material can be ethylene vinyl acetate (EVA) or polyvinyl butyral (PVB). In an embodiment, the non-conductive white paint includes at least a medium and pigments dispersed in the medium. The medium is, for example, a paint or a polymer for plastic, and the pigments are, for example, oxide particles (e.g. TiO₂ or BaSO₄), nitride particles or carbide particles, etc. A method of forming the non-conductive reflector 110 is to, for example, coat the white non-conductive material on the top through a spin coating or a screen printing after the electrode 108 is formed.

According to FIG. 1, it is known that the light L is incident into the solar cell 100 from the side of the transparent substrate 102, and after the light L enters the transparent substrate 102, it is absorbed by the photoelectric conversion layer 106. After the remained light penetrates through the electrode 108, the remained light is reflected by the non-conductive reflector 110, and is again absorbed by the photoelectric conversion layer 106, so that more photocurrents are generated. Therefore, a whole amount of the light reflected by the non-conductive reflector 110 influences a whole performance of the solar cell 100.

Particularly, the solar cell 100 of the present embodiment uses the nano-metal transparent conductive layer as the material of the back electrode 108 instead of using the conventional TCO, so as to achieve characteristics of high light transmittance and low resistance, and avail increasing the reflectance of the non-conductive reflector 110 and improving the performance of the solar cell 100. In detail, when the non-conductive material is used as the back reflector, to pull more currents from the conventional TCO used as the back electrode, a thickness of the TCO has to be increased to obtain a better conductivity, though the light transmittance thereof is significantly decreased, accordingly. In the present invention, the nano-metal transparent conductive layer is used to increase the light transmittance of the back electrode, so as to increase the whole reflectance of the reflector, and accordingly more reflected light can be used by the photoelectric conversion layer 106. Moreover, compared to the conventional TCO used as the back electrode, the nano-metal transparent conductive layer is a metal material with relatively low resistance, so that the electrode 108 has a high conductivity.

To ensure that the nano-metal transparent conductive layer of the back electrode of the solar cell of the present invention indeed has the high transmittance and high conductivity, experiments are provided below to describe the characteristics thereof. Data results of the following experiments are only used for describing the observed structures, transmittances and sheet resistances of the transparent conductive film fabricated by using the nano-metal organic solutions with different weight percentages, which are not used for limiting the present invention.

### Experiment 1

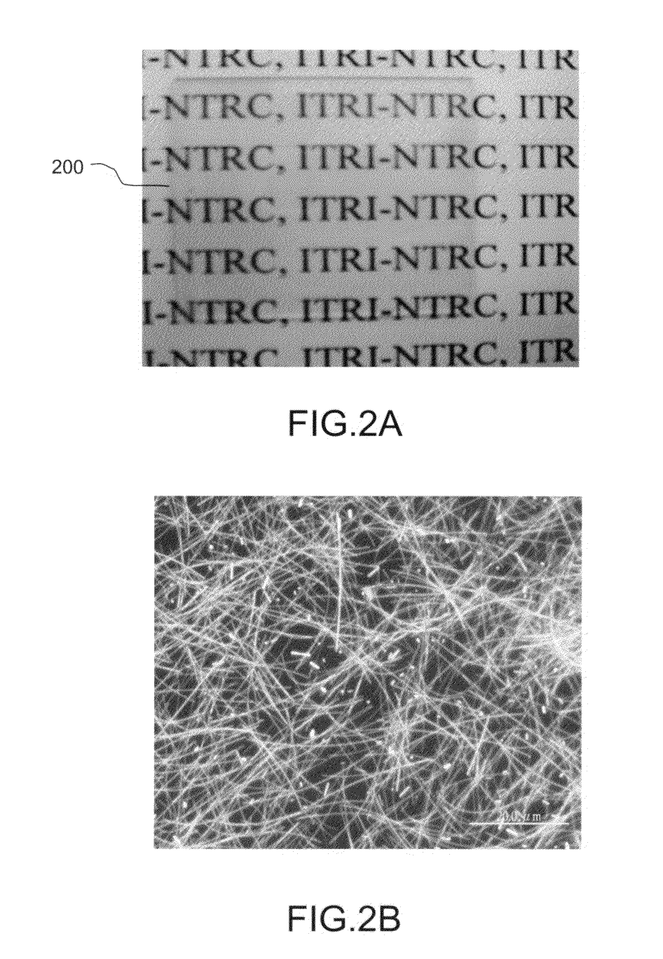

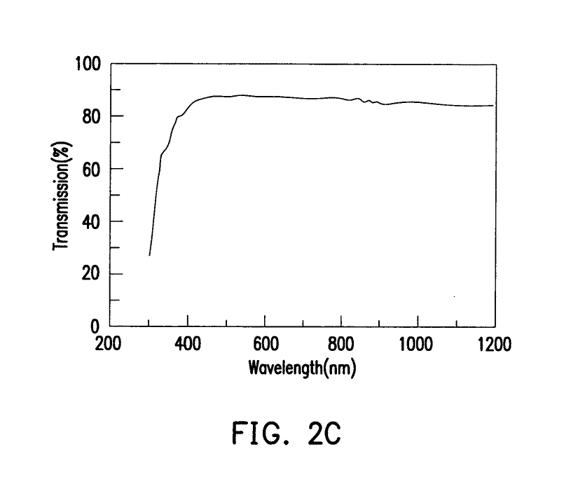

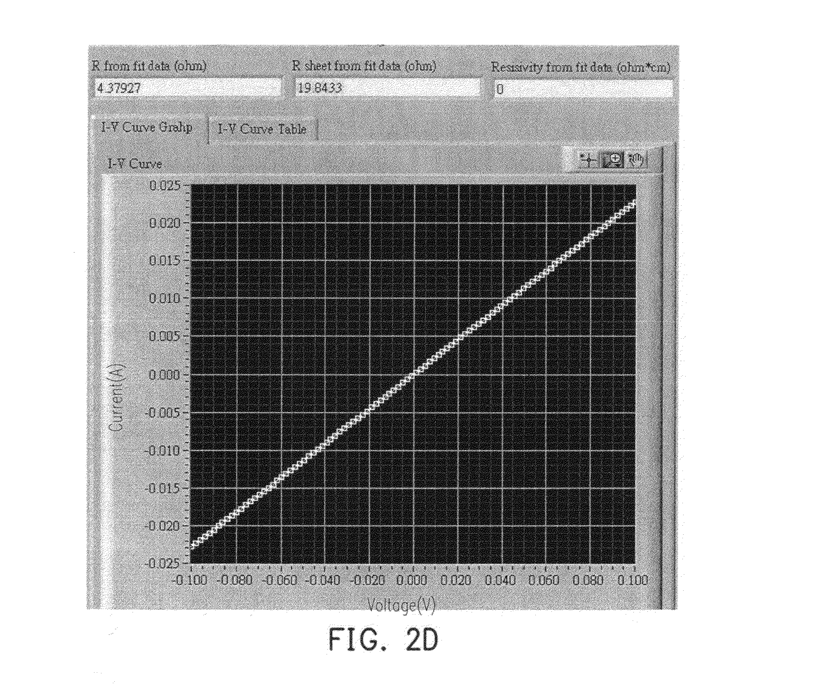

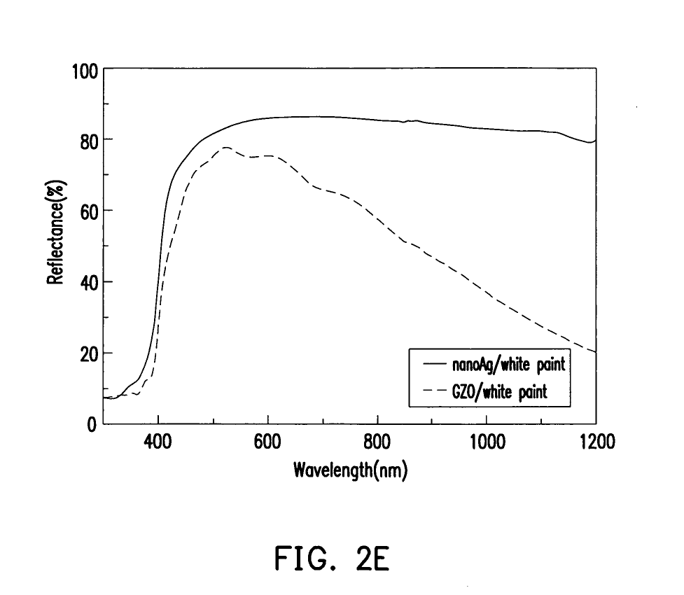

FIG. 2A is a diagram illustrating a transparent conductive film fabricated according to the experiment 1. FIG. 2B is an image of the transparent conductive film fabricated according to the experiment 1 that is observed under an optical microscope.

In the experiment 1, a 0.2 wt % nano-silver organic solution is evenly coated on a glass substrate, and then the liquid is dried under a low temperature of 50° C., so as to fabricate a transparent nano-silver conductive film, wherein a thickness thereof is about 0.5 μm. As shown in FIG. 2A, by disposing a glass substrate 200 where the nano-silver conductive film of the experiment 1 is formed on a pattern, it is observed that the pattern under the glass substrate 200 can still be clearly identified even through the nano-silver conductive film. Therefore, the nano-silver conductive film fabricated according to the experiment 1 has the high transmittance. As shown in FIG. 2B, when the transparent nano-silver conductive film is observed through an optical microscope, it is obvious that the nano-silver conductive film has a mesh structure formed by a plurality of interlaced silver nanowires, and a plurality of voids is formed between the interlaced silver nanowires. Therefore, the nano-silver conductive film has a high light transmittance.

FIG. 2C is a curve diagram illustrating a relationship between transmission rate of the transparent conductive film fabricated according to the experiment 1 and light wavelength. Lights of different wavelengths are used to measure the transmittances of the transparent nano-silver conductive film, and results thereof are shown in FIG. 2C. According to FIG. 2C, it is known that regardless of using the light with a short wavelength or a long wavelength, the transparent nano-silver conductive film fabricated according to the experiment 1 all has a good light transmittance. In addition, an average transmittance of the transparent nano-silver conductive film is 85.4% (the wavelength is between 390 nm and 1200 nm).

FIG. 2D is an I-V curve diagram of the transparent conductive film fabricated according to the experiment 1. An electrical measurement is performed to the nano-silver conductive film fabricated according to the experiment 1, and the I-V characteristic relation diagram obtained according to a measured result thereof is as that shown in FIG. 2D. According to the I-V characteristic relation diagram, it can be deduced that an average sheet resistance of the nano-silver conductive film is 31.1±9.2Ω/□, and a minimum sheet resistance of the nano-silver conductive film is 19.8Ω/□.

FIG. 2E is a curve diagram illustrating relationships respectively between reflectances of the transparent conductive film fabricated according to the experiment 1 and the conventional TCO and light wavelength. A white paint is coated on the nano-silver conductive film fabricated according to the experiment 1 to serve as the reflector, and a whole light reflectance of the reflector is measured. Moreover, a comparison example is fabricated, by which the GZO with a thickness of 1 μm is plated on the glass substrate to serve as the back electrode using the conventional TCO, and then the white paint is coated, and the reflectance thereof is measured. By comparing the comparison example of the conventional TCO to the design of the experiment 1, a result thereof is as that shown in FIG. 2E.

According to FIG. 2E, it is known that the reflectances of the experiment 1 can be more than 80% in case of short wavelengths (400 nm-800 nm). When the wavelength is greater than 800 nm, the back electrode using the conventional TCO can lead to an obvious decrease of the whole reflectance of the reflector due to an influence of carrier absorption under a relatively great thickness of the TCO. However, different to the comparison example, the back electrode using the nano-silver conductive film of the experiment 1 does not lead to the reflectance decrease problem caused by carrier concentration. Therefore, the transparent nano-silver conductive film fabricated according to the experiment 1 can greatly increase the whole reflectance of the reflector. Moreover, in a further simulation, regarding a microcrystalline silicon solar cell device, an original short circuit current density Jsc of the device is 18.98 mA/cm², while after the transparent nano-silver conductive film fabricated according to the experiment 1 is used as the back electrode of the microcrystalline silicon solar cell, the short circuit current density Jsc can be increased to 20.04 mA/cm². Particularly, in case of the long wavelengths (700 nm-1100 nm), the short circuit current density Jsc of the microcrystalline silicon solar cell can be increased to 5.19 mA/cm² from 4.13 mA/cm², which is increased about 20%.

### Experiment 2

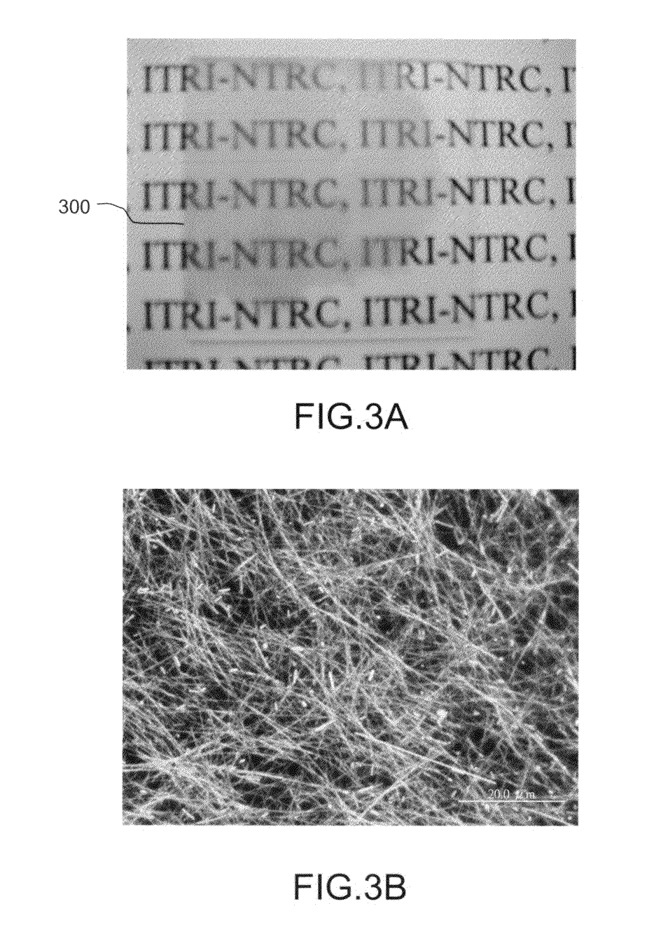

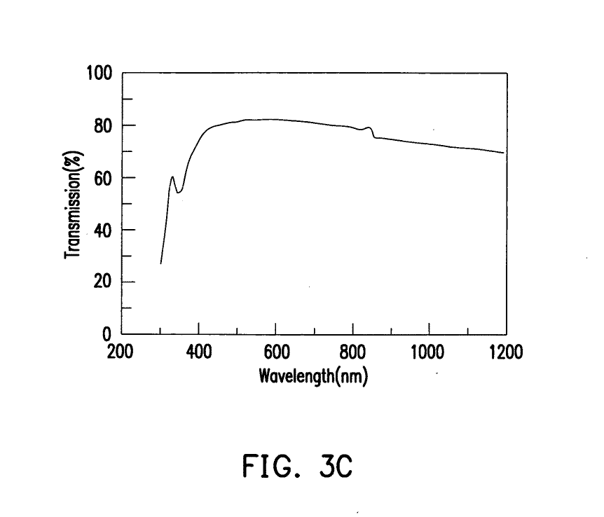

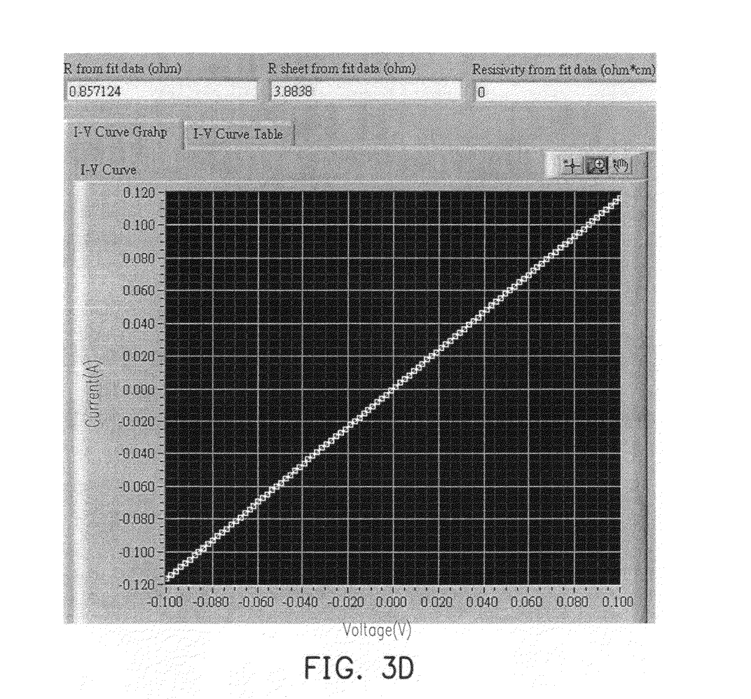

FIG. 3A is a diagram illustrating a transparent conductive film fabricated according to the experiment 2. FIG. 3B is an image of the transparent conductive film fabricated according to the experiment 2 that is observed under an optical microscope. FIG. 3C is a curve diagram illustrating a relationship between transmission rate of the transparent conductive film fabricated according to the experiment 2 and light wavelength. FIG. 3D is an I-V curve diagram of the transparent conductive film fabricated according to the experiment 2.

In the experiment 2, a 0.8 wt % nano-silver organic solution is used to evenly coat on a glass substrate, and a transparent nano-silver conductive film is fabricated according to a method similar as that of the experiment 1, wherein a thickness thereof is about 0.8 μm. Then, the related tests similar as that in the experiment 1 are performed to the transparent nano-silver conductive film fabricated according to the experiment 2, and results thereof are respectively shown in FIGS. 3A-3D.

Similarly, in FIG. 3A, by disposing a glass substrate 300 where the nano-silver conductive film of the experiment 2 is formed on a pattern, it is observed that the pattern under the glass substrate 300 can still be clearly identified through the nano-silver conductive film. Therefore, the nano-silver conductive film fabricated according to the experiment 2 has the high transmittance. As shown in FIG. 3B, when the transparent nano-silver conductive film is observed through an optical microscope, it is obvious that the nano-silver conductive film is a mesh structure formed by a plurality of interlaced silver nanowires, and a plurality of voids is formed between the interlaced silver nanowires. Therefore, the nano-silver conductive film has a high light transmittance.

According to FIG. 3C, lights of different wavelengths are used to measure the transmittances of the transparent nano-silver conductive film, and it is known that regardless of using the light with a short wavelength or a long wavelength, the nano-silver conductive film fabricated according to the experiment 2 all has a good light transmittance, and an average transmittance of the nano-silver conductive film is 70.3% (the wavelength is between 390 nm and 1200 nm).

As shown in FIG. 3D, an electrical measurement is performed to the nano-silver conductive film fabricated according to the experiment 2, and according to the I-V characteristic relation diagram, it can be deduced that an average sheet resistance of the nano-silver conductive film is 4.7±0.5Ω/□, and a minimum sheet resistance of the nano-silver conductive film is 3.9Ω/□.

According to the above experiments, it is known that in the solar cell of the present invention, since the nano-metal transparent conductive layer has characteristics of high light transmittance and low resistance, the whole reflectance can be increased to achieve an optimal usage rate of the sunlight, and the short circuit current density and the device efficiency can be increased.

In summary, in the solar cell of the present invention, the nano-metal transparent conductive layer having the high transmittance and high conductivity is used to replace the conventional TCO to serve as the back electrode, and the non-conductive white reflector is further coated on the nano-metal transparent conductive layer, so as to improve the reflectance of the back reflector. Furthermore, a problem can be mitigated that the reflectance of the whole reflector is decreased due to a low transmittance of the TCO used as the back electrode when a thickness of the TCO is more than 0.5 μm. Namely, in the solar cell of the present invention, the transmittance of the back electrode can be increased to improve the whole reflectance, so that more reflected light can be again used by the photoelectric conversion layer, and a whole performance of the solar cell can be improved.

Moreover, according to the method of fabricating the solar cell of the present invention, the nano-metal organic solution is applied to the back electrode of the silicon thin film solar cell through coating, ink jetting or screen printing, etc. without using a vacuum coating technique, and a laser cutting process is saved, so that the equipment cost and the material cost can be greatly reduced. Moreover, the method of the present invention can be integrated to an existing fabrication process of the solar cell, so that the fabrication process can be simple and quick, which avails a mass production of the solar cell.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell, comprising:
a first electrode, disposed on a transparent substrate, and including a nano-metal transparent conductive layer;
a photoelectric conversion layer, disposed between the first electrode and the transparent substrate;
a second electrode, disposed between the photoelectric conversion layer and the transparent substrate; and
a non-conductive reflector, disposed on the first electrode,
wherein the nano-metal transparent conductive layer substantially contacts with the photoelectric conversion layer.

2. The solar cell as claimed in claim 1, wherein the nano-metal transparent conductive layer has a mesh structure.

3. The solar cell as claimed in claim 1, wherein the nano-metal transparent conductive layer is formed by a plurality of interlaced metal nanowires.

4. The solar cell as claimed in claim 1, wherein a material of the nano-metal transparent conductive layer comprises silver, gold, copper, aluminium or nickel.

5. The solar cell as claimed in claim 1, wherein a thickness of the nano-metal transparent conductive layer is between 0.1 μm and 1 μm.

6. The solar cell as claimed in claim 1, wherein a sheet resistance of the nano-metal transparent conductive layer is between 0.01 ohms per square (Ω/□) and 50 Ω/□.

7. The solar cell as claimed in claim 1, wherein a transmittance of the nano-metal transparent conductive layer is between 70% and 90%.

8. The solar cell as claimed in claim 1, wherein the non-conductive reflector comprises a white non-conductive material.

9. The solar cell as claimed in claim 8, wherein the white non-conductive material is an organic polymer material or a non-conductive white paint.

10. The solar cell as claimed in claim 9, wherein the organic polymer material comprises ethylene vinyl acetate (EVA) or polyvinyl butyral (PVB).

11. The solar cell as claimed in claim 1, wherein the second electrode has texture structures.

12. The solar cell as claimed in claim 1, wherein a material of the second electrode comprises transparent conductive oxide (TCO).

13. The solar cell as claimed in claim 11, wherein the TCO is indium tin oxide (ITO), indium zinc oxide (IZO), Al doped zinc oxide (AZO), Ga doped zinc oxide (GZO), In₂O₃, ZnO, TiO₂, or SnO₂.

14. A method for fabricating a solar cell, comprising:
forming a second electrode on a transparent substrate;
forming a photoelectric conversion layer on the second electrode;
forming a first electrode on the photoelectric conversion layer, wherein the first electrode comprises a nano-metal transparent conductive layer, and the nano-metal transparent conductive layer substantially contacts with the photoelectric conversion layer; and
forming a non-conductive reflector on the first electrode.

15. The method for fabricating the solar cell as claimed in claim 14, wherein the step of forming the nano-metal transparent conductive layer comprises:
coating a nano-metal organic solution on the photoelectric conversion layer; and
drying the nano-metal organic solution to form a film on a surface of the photoelectric conversion layer.

16. The method for fabricating the solar cell as claimed in claim 15, wherein the step of coating the nano-metal organic solution on the photoelectric conversion layer comprises spin coating, surface coating, ink jetting or screen printing.

17. The method for fabricating the solar cell as claimed in claim 14, wherein the nano-metal transparent conductive layer has a mesh structure.

18. The method for fabricating the solar cell as claimed in claim 14, wherein the nano-metal transparent conductive layer is formed by a plurality of interlaced metal nanowires.

19. The method for fabricating the solar cell as claimed in claim 14, wherein a material of the nano-metal transparent conductive layer comprises silver, gold, copper, aluminium or nickel.

20. The method for fabricating the solar cell as claimed in claim 14, wherein a thickness of the nano-metal transparent conductive layer is between 0.1 μm and 1 μm.

21. The method for fabricating the solar cell as claimed in claim 14, wherein a sheet resistance of the nano-metal transparent conductive layer is between 0.01Ω/□ and 50Ω/□.

22. The method for fabricating the solar cell as claimed in claim 14, wherein a transmittance of the nano-metal transparent conductive layer is between 70% and 90%.

23. The method for fabricating the solar cell as claimed in claim 14, wherein the non-conductive reflector comprises a white non-conductive material.

24. The method for fabricating the solar cell as claimed in claim 23, wherein the white non-conductive material is an organic polymer material or a non-conductive white paint.

25. The solar cell as claimed in claim 24, wherein the organic polymer material comprises ethylene vinyl acetate (EVA) or polyvinyl butyral (PVB).

26. The method for fabricating the solar cell as claimed in claim 14, further comprising forming texture structures on a surface the second electrode.

27. The method for fabricating the solar cell as claimed in claim 14, wherein a material of the second electrode comprises transparent conductive oxide (TCO).

28. The method for fabricating the solar cell as claimed in claim 27, wherein the TCO is indium tin oxide (ITO), indium zinc oxide (IZO), Al doped zinc oxide (AZO), Ga doped zinc oxide (GZO), In₂O₃, ZnO, TiO₂, or SnO₂.
